(19) United States
(12) Patent Application Publication
(10) Pub. No.: US 2015/0021657 A1
(43) Pub. Date: Jan. 22, 2015

(54) SEMICONDUCTOR DEVICE

(71) Applicant: Kabushiki Kaisha Toshiba, Tokyo (JP)

(72) Inventors: Tsuneo Ogura, Kanagawa-ken (JP); Kazutoshi Nakamura, Ishikawa-ken (JP)

(73) Assignee: Kabushiki Kaisha Toshiba, Tokyo (JP)

(21) Appl. No.: 14/203,009

(22) Filed: Mar. 10, 2014

(30) Foreign Application Priority Data
Jul. 18, 2013 (JP) 2013-149344

(51) Int. Cl. H01L 29/739

(52) U.S. Cl. CPC H01L 29/7393
USPC 257/139

(57) ABSTRACT

According to one embodiment, a semiconductor device includes: first and second electrodes; a first semiconductor region being in ohmic contact with the first electrode; a second semiconductor region being in contact with the first semiconductor region and the first electrode, and the second semiconductor region having a lower impurity concentration than the first semiconductor region; a first semiconductor layer; a second semiconductor layer; a third semiconductor region; a fourth semiconductor region being in contact with the second electrode; and a third electrode in contact with the second semiconductor layer, the third semiconductor region, and the fourth semiconductor region via an insulating film. A peak of impurity concentration profile of the first semiconductor layer in a direction from the first electrode toward the second electrode is located between the first semiconductor region and the second semiconductor layer and located between the second semiconductor region and the second semiconductor layer.

### CROSS-REFERENCE TO RELATED APPLICATIONS

This application is based upon and claims the benefit of priority from Japanese Patent Application No. 2013-149344, filed on Jul. 18, 2013; the entire contents of which are incorporated herein by reference.

### FIELD

Embodiments described herein relate generally to a semiconductor device.

### BACKGROUND

The IGBT (insulated gate bipolar transistor) is a typical example of power semiconductor devices. The speed of IGBT can be accelerated by reducing the dose amount of the p-type semiconductor layer provided on the collector electrode side. By reducing the dose amount of the p-type semiconductor layer, the amount of holes injected from the collector electrode side is decreased. As a result, the turn-off loss of the IGBT is reduced. This accelerates switching of the IGBT.

However, reducing the dose amount of the p-type semiconductor layer means degradation of ohmic contact between the collector electrode and the p-type semiconductor layer. This causes such phenomena as variation of on-voltage for different IGBTs and saturation of the switching rate of the IGBT. For IGBTs, improvement in these electrical characteristics is desired.

### BRIEF DESCRIPTION OF THE DRAWINGS

FIGS. 1A to 1C are schematic views showing a semiconductor device according to a first embodiment, FIG. 1A is a schematic sectional view of the semiconductor device, and FIGS. 1B and 1C are schematic plan views of the semiconductor device;

FIG. 2A is a schematic sectional view showing the semiconductor device according to the first embodiment, and FIG. 2B shows impurity concentration profiles of the first semiconductor device;

FIG. 3 is a schematic sectional view showing the operation of the on-state of the semiconductor device according to the first embodiment;

FIG. 4A is a schematic sectional view showing the state after turn-off of the semiconductor device according to the first embodiment, and FIGS. 4B and 4C show impurity concentration profiles of semiconductor devices according to reference examples;

FIGS. 5A and 5B show the result of simulating the state of carriers spreading in the semiconductor device;

FIG. 6A shows the relationship between the film thickness and the initial value of the tail current, and FIG. 6B shows the current flowing between the emitter and the collector after turn-off;

FIG. 7 is a schematic sectional view showing a semiconductor device according to a variation of the first embodiment;

FIGS. 8A and 8B are schematic sectional views showing semiconductor devices according to alternative variations of the first embodiment;

FIGS. 9A to 9C are schematic views showing a semiconductor device according to a second embodiment, FIG. 9A is a schematic sectional view of the semiconductor device, and FIGS. 9B and 9C are schematic plan views of the semiconductor device;

FIG. 10 is a schematic sectional view showing the operation of the on-state of the semiconductor device according to the second embodiment;

FIG. 11 is a schematic sectional view showing a semiconductor device according to a variation of the second embodiment;

FIG. 12 is a schematic plan view showing a semiconductor device according to a third embodiment; and

FIG. 13 is a schematic plan view showing a semiconductor device according to a fourth embodiment.

### DETAILED DESCRIPTION

In general, according to one embodiment, a semiconductor device includes: a first electrode; a second electrode; a first semiconductor region of a first conductivity type provided between part of the first electrode and the second electrode, and the first semiconductor region being in ohmic contact with the first electrode; a second semiconductor region of the first conductivity type provided between a portion other than the part of the first electrode and the second electrode, the second semiconductor region being in contact with the first semiconductor region and the first electrode, and the second semiconductor region having a lower impurity concentration than the first semiconductor region; a first semiconductor layer of a second conductivity type provided between the first semiconductor region and the second electrode and provided between the second semiconductor region and the second electrode; a second semiconductor layer of the second conductivity type provided between the first semiconductor layer and the second electrode; a third semiconductor region of the first conductivity type provided between the second semiconductor layer and the second electrode; a fourth semiconductor region of the second conductivity type provided between part of the third semiconductor region and the second electrode, and the fourth semiconductor region being in contact with the second electrode; and a third electrode in contact with the second semiconductor layer, the third semiconductor region and the fourth semiconductor region via an insulating film.

A peak of impurity concentration profile of the first semiconductor layer in a direction from the first electrode toward the second electrode is located between the first semiconductor region and the second semiconductor layer and located between the second semiconductor region and the second semiconductor layer.

Embodiments will now be described with reference to the drawings. In the following description, like members are labeled with like reference numerals, and the description of the members once described is omitted appropriately. The embodiments and figures described below can be combined as long as technically feasible, and the combined embodiments are also encompassed within the scope of the present embodiments.

### First Embodiment

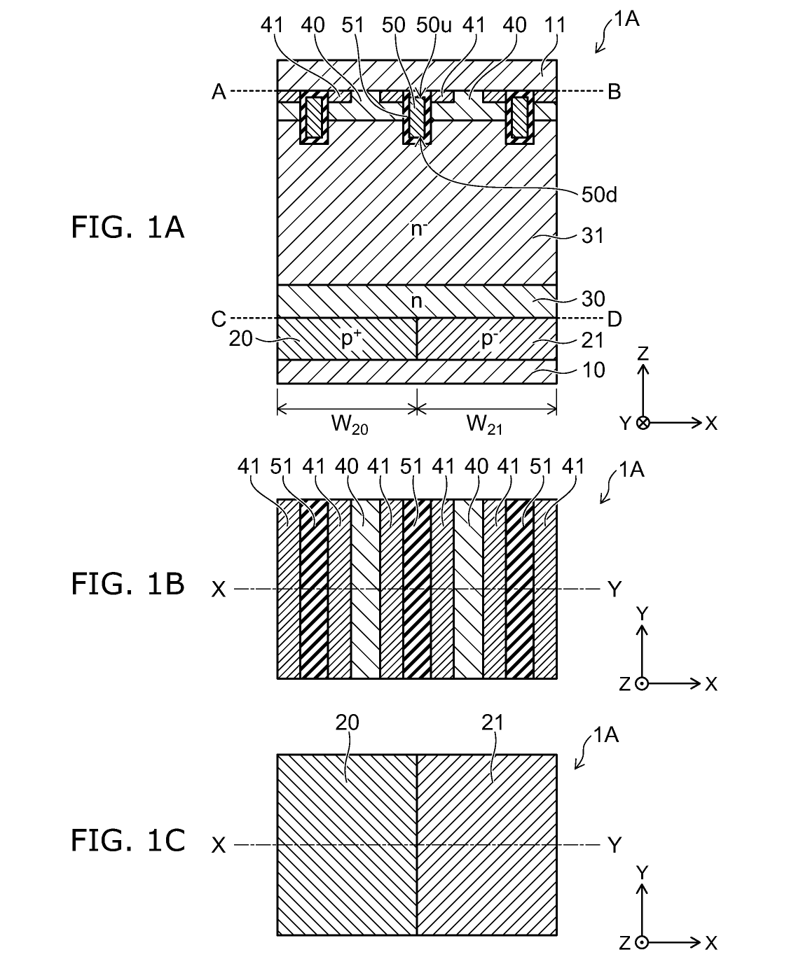

FIGS. 1A to 1C are schematic views showing a semiconductor device according to a first embodiment. FIG. 1A is a schematic sectional view of the semiconductor device. FIGS. 1B and 1C are schematic plan views of the semiconductor device.

FIG. 1A shows a cross section taken along the position of line X-Y in FIGS. 1B and 1C. FIG. 1B shows an A-B cross section of FIG. 1A. FIG. 1C shows a C-D cross section of FIG. 1A.

The semiconductor device 1A shown in FIGS. 1A to 1C is an IGBT. The semiconductor device 1A includes a collector electrode 10 (first electrode), a p⁺-type collector region 20 (first semiconductor region), a p⁻-type collector region 21 (second semiconductor region), an n-type buffer layer 30 (first semiconductor layer), an n⁻-type base layer 31 (second semiconductor layer), a p-type base region 40 (third semiconductor region), an n⁺-type emitter region 41 (fourth semiconductor region), a gate electrode 50 (third electrode), a gate insulating film 51, and an emitter electrode 11 (second electrode). The p⁺-type collector region 20, the p⁻-type collector region 21, the n-type buffer layer 30, the n⁻-type base layer 31, the p-type base region 40, the n⁺-type emitter region 41, the gate electrode 50, and the gate insulating film 51 are provided between the collector electrode 10 and the emitter electrode 11.

In FIGS. 1A to 1C, the direction from the collector electrode 10 toward the emitter electrode 11 is matched with the Z-axis in the three-dimensional coordinate system. An axis crossing (being orthogonal to) the Z-axis is identified with the X-axis. An axis crossing (being orthogonal to) the Z-axis and the X-axis is identified with the Y-axis. The Y-axis is matched with e.g. the extending direction of the gate electrode 50.

In the embodiments, the Z-direction from the collector electrode 10 toward the emitter electrode 11 is a first direction. The Y-direction crossing the Z-direction is a second direction. The X-direction crossing the Z-direction and the X-direction is a third direction.

In FIGS. 1A to 1C, for instance, a minimum unit of the semiconductor device 1A is shown. In an actual semiconductor device 1A, the semiconductor device 1A shown in FIGS. 1A to 1C is periodically repeated in the X-direction. That is, the minimum unit is a semiconductor element, and the semiconductor device 1A is a semiconductor device in which a plurality of semiconductor elements are collected. The length in the Y-direction of FIGS. 1B and 1C is part of the length in the Y-direction of the actual semiconductor device 1A.

The p⁺-type collector region 20 is provided on part of the collector electrode 10. The p⁺-type collector region 20 is provided between part of the collector electrode 10 and the emitter electrode 11. The p⁺-type collector region 20 is a high-concentration p-type region. The p⁺-type collector region 20 is in ohmic contact with the collector electrode 10. The ohmic contact refers to a contact having a nearly constant resistance value independent of the direction of the current and the magnitude of the voltage. That is, the ohmic contact is a non-rectifying contact.

The p⁻-type collector region 21 is provided on the portion of the collector electrode 10 other than the portion on which the p⁺-type collector region 20 is provided. The p⁻-type collector region 21 is provided between the emitter electrode 11 and the portion of the collector electrode 10 other than the portion on which the p⁺-type collector region 20 is provided. The impurity concentration of the p⁻-type collector region 21 is lower than the impurity concentration of the p⁺-type collector region 20. The p⁻-type collector region 21 is in ohmic contact or Schottky contact with the collector electrode 10. The Schottky contact refers to a contact between a metal and a semiconductor such that the contact has a Schottky barrier between the metal and the semiconductor. The Schottky contact is a rectifying contact. The p⁻-type collector region 21 is a low-concentration p-type region. The p⁻-type collector region 21 is in contact with the p⁺-type collector region 20.

The collector electrode 10 connected to the p⁻-type collector region 21 and the collector electrode 10 connected to the p⁺-type collector region 20 are integrated. That is, the p⁻-type collector region 21 and the p⁺-type collector region 20 are provided on the same collector electrode 10.

As described above, the semiconductor device 1A shown in FIGS. 1A to 1C is a minimum unit of the IGBT. In an actual semiconductor device 1A, a plurality of p⁺-type collector regions 20 and a plurality of p⁻-type collector regions 21 are arranged alternately one by one in the X-direction.

The p⁺-type collector region 20 and the p⁻-type collector region 21 each extend in the Y-direction (FIG. 1C). The width W₂₀ in the X-direction of the p⁺-type collector region 20 is e.g. 1-100 μm. Thus, in general, each width of the p⁺-type collector region 20 and the p⁻-type collector region 21 is designed independently of the pitch of the trench structure in the A-B cross section. The width W₂₁ in the X-direction of the p⁻-type collector region 21 is e.g. 1-100 μm. In the arranging direction of the p⁺-type collector region 20 and the p⁻-type collector region 21, (width W₂₁)/(width W₂₀) is equal to e.g. 0.1-10 (0.1 or more and 10 or less).

The thickness of the p⁺-type collector region 20 is several tens μm or less. More preferably, the thickness of the p⁺-type collector region 20 is 2 μm or less (described later). The thickness of the p⁻-type collector region 21 is several tens μm or less. More preferably, the thickness of the p⁻-type collector region 21 is 2 μm or less.

The n-type buffer layer 30 is provided on the p⁺-type collector region 20 and on the p⁻-type collector region 21. The n⁻-type base layer 31 is provided on the n-type buffer layer 30. The thickness of the n⁻-type base layer 31 is e.g. 10-500 μm. The thickness of the n⁻-type base layer 31 is designed as appropriate depending on the breakdown voltage of the device. The n⁻-type base layer 31 is also referred to as n⁻-type drift layer 31.

The p-type base region 40 is provided on the n⁻-type base layer 31. The n⁺-type emitter region 41 is provided on part of the p-type base region 40. The n⁺-type emitter region 41 is provided between part of the p-type base region 40 and the emitter electrode 11. The n⁺-type emitter region 41 is in contact with the emitter electrode 11. The n⁺-type emitter region 41 and the p-type base region 40 each extend in the Y-direction (FIG. 1B).

The gate electrode 50 is in contact with the n⁻-type base layer 31, the p-type base region 40, and the n⁺-type emitter region 41 via the gate insulating film 51. The upper end 50u of the gate electrode 50 is located at the height of the n⁺-type emitter region 41. The lower end 50d of the gate electrode 50 is located at the height of the n⁻-type base layer 31. The gate electrode 50 extends in the Y-direction (FIG. 1B). The number of gate electrodes 50 per minimum unit is not limited to the number shown in FIGS. 1A to 1C. In other words, the channel density per minimum unit is set as appropriate depending on the current capacity of the device.

The emitter electrode 11 is provided on the n⁺-type emitter region 41 and on the p-type base region 40.

The p⁺-type collector region 20, the p⁻-type collector region 21, the n-type buffer layer 30, the n⁻-type base layer 31, the p-type base region 40, and the n⁺-type emitter region 41 each include e.g. silicon (Si). The impurity element of the conductivity type such as p⁺-type, p⁻-type, and p-type (first conductivity type) is e.g. boron (B) or the like. The impurity element of the conductivity type such as n⁺-type, n⁻-type, and n-type (second conductivity type) is e.g. phosphorus (P), arsenic (As) or the like.

The gate electrode 50 includes e.g. polysilicon, metal or the like doped with an impurity element. The gate insulating film 51 includes e.g. silicon oxide (SiO₂). The collector electrode 10 and the emitter electrode 11 each include e.g. a metal including at least one selected from the group consisting of aluminum (Al), titanium (Ti), nickel (Ni), tungsten (W), gold (Au) and the like.

In the embodiments, the “concentration of the impurity element (impurity concentration)” refers to the effective concentration of the impurity element contributing to the conductivity of the semiconductor material. For instance, in the case where the semiconductor material contains an impurity element serving as a donor and an impurity element serving as an acceptor, the impurity concentration is defined as the concentration of the activated impurity elements exclusive of the donor and the acceptor canceling out each other.

The concentration of the impurity element contained in the n⁻-type base layer 31 is lower than the concentration of the impurity element contained in the n⁺-type emitter region 41. The concentration of the impurity element contained in the n⁻-type base layer 31 is lower than the concentration of the impurity element contained in the n-type buffer layer 30.

The concentration of the impurity element contained in the p⁺-type collector region 20 is higher than the concentration of the impurity element contained in the p⁻-type collector region 21. For instance, the concentration of the impurity element contained in the p⁺-type collector region 20 at the surface in contact with the collector electrode 10 is higher than the concentration of the impurity element contained in the p⁻-type collector region 21 at the surface in contact with the collector electrode 10.

The concentration of the impurity element contained in the p⁺-type collector region 20 at the surface in contact with the collector electrode 10 is higher than 3×10¹⁷ atoms.cm⁻³, such as 1×10¹⁹ atoms.cm⁻³ or more. The impurity concentration of the p⁺-type collector region 20 may be set higher toward the collector electrode 10 side.

The impurity concentration of the p⁻-type collector region 21 at the surface in contact with the collector electrode 10 is e.g. 1×10¹⁵ cm⁻³ or more and 3×10¹⁷ cm⁻³ or less. The impurity concentration of the p⁻-type collector region 21 may be set lower toward the collector electrode 10 side.

The impurity concentration of the n⁺-type emitter region 41 at the surface in contact with the emitter electrode 11 is higher than 3×10¹⁷ cm⁻³, such as 1×10¹⁹ cm⁻³ or more. The impurity concentration of the n⁻-type base layer 31 is 1×10¹⁵ cm⁻³ or less, and can be set to an arbitrary impurity concentration depending on the breakdown voltage design of the device.

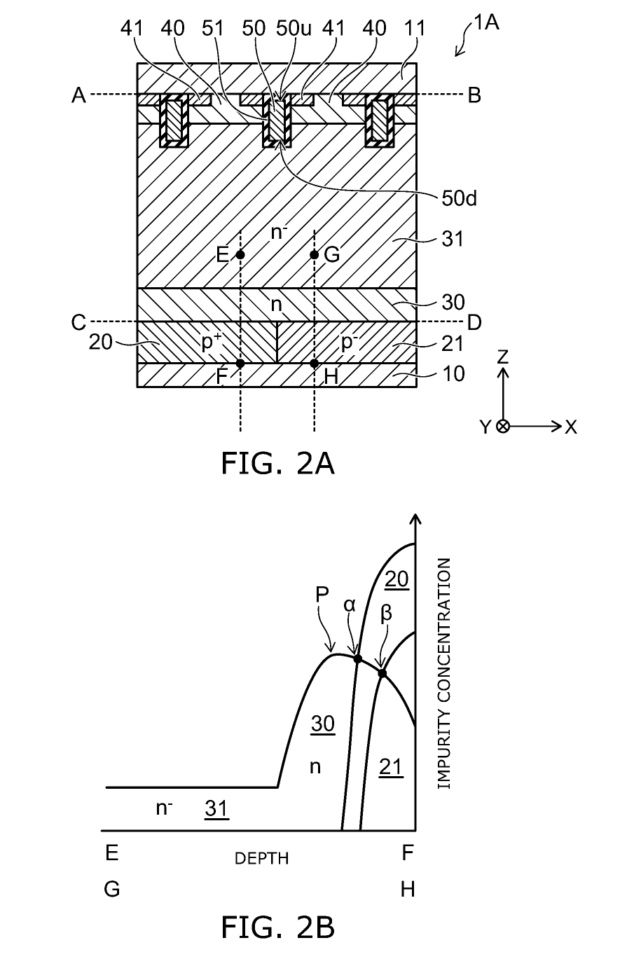

FIG. 2A is a schematic sectional view showing the semiconductor device according to the first embodiment. FIG. 2B shows impurity concentration profiles of the first semiconductor device.

FIG. 2B shows impurity concentration profiles of the n⁻-type base layer 31, the n-type buffer layer 30, and the p⁺-type collector region 20 at positions along the line connecting point E to point F in FIG. 2A. Furthermore, FIG. 2B shows impurity concentration profiles of the n⁻-type base layer 31, the n-type buffer layer 30, and the p⁻-type collector region 21 at positions along the line connecting point G to point H in FIG. 2A.

As shown in FIG. 2B, the impurity concentration profiles of the p⁺-type collector region 20 and the p⁻-type collector region 21 increase from the emitter electrode 11 side toward the collector electrode 10 side. Subsequently, the impurity concentration profile of the n-type buffer layer 30 once increases from the emitter electrode 11 side toward the collector electrode 10 side, and then decreases.

That is, the peak P of the impurity concentration profile of the n-type buffer layer 30 in the Z-direction is located between the p⁺-type collector region 20 and the n⁻-type base layer 31. The peak P of the impurity concentration profile of the n-type buffer layer 30 in the Z-direction is located between the p⁻-type collector region 21 and the n⁻-type base layer 31. In other words, the peak P is located on the emitter electrode 11 side of the intersection point α of the impurity concentration profile of the p⁺-type collector region 20 and the impurity concentration profile of the n-type buffer layer 30. Furthermore, the peak P is located on the emitter electrode 11 side of the intersection point β of the impurity concentration profile of the p⁻-type collector region 21 and the impurity concentration profile of the n-type buffer layer 30. The impurity concentration of the n-type buffer layer 30 at the position of the peak P is e.g. 1×10¹⁵-1×10¹⁷ cm⁻³.

The operation of the semiconductor device 1A is now described.

In operating the semiconductor device 1A, the emitter electrode 11 is applied with a ground potential (or negative potential), and the collector electrode 10 is applied with a positive potential. Between the emitter electrode 11 and the collector electrode 10, a voltage of e.g. several hundred V is applied.

In the off-state of the semiconductor device 1A, the potential of the gate electrode 50 is lower than the threshold potential. Thus, no channel region (inversion layer) is formed in the p-type base region 40 along the gate electrode 50 via the gate insulating film 51. Accordingly, no current flows between the emitter electrode 11 and the collector electrode 10.

The on-state of the semiconductor device 1A is now described.

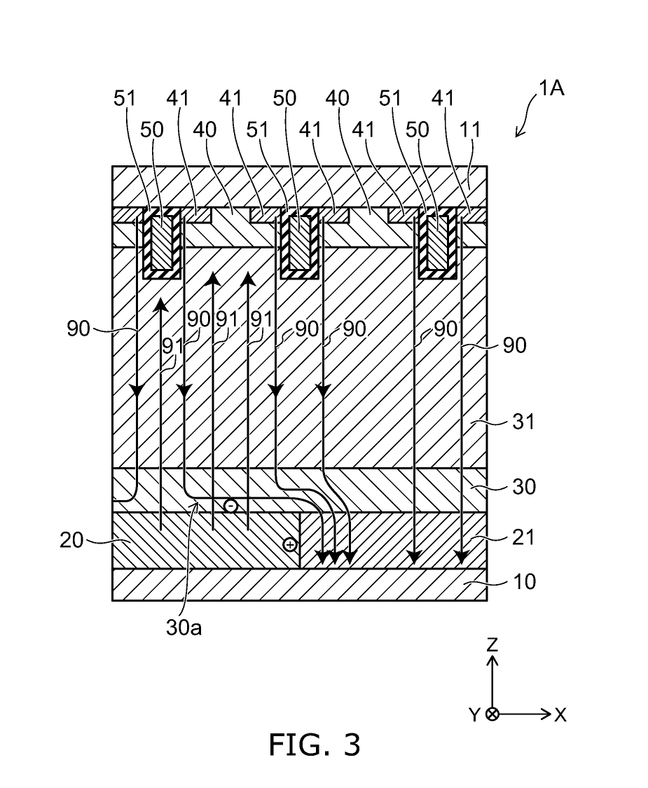

FIG. 3 is a schematic sectional view showing the operation of the on-state of the semiconductor device according to the first embodiment.

If the potential of the gate electrode 50 of the semiconductor device 1A increases to the threshold potential or more, the semiconductor device 1A is turned on. Then, a channel region is formed in the p-type base region 40. Thus, electrons e injected from the emitter electrode 11 into the n⁺-type emitter region 41 pass through the channel region of the p-type base region 40 to the n⁻-type base layer 31. Furthermore, the electrons e reach the n-type buffer layer 30. In the figure, the electron current based on the electrons e is schematically denoted by reference numeral 90.

In the semiconductor device 1A, the p⁻-type collector region 21 and the collector electrode 10 are in ohmic contact or Schottky contact with each other. Thus, for holes h moving from the collector electrode 10 side toward the emitter electrode 11 side, the junction between the p⁻-type collector region 21 and the collector electrode 10 may serve as an energy barrier.

However, for electrons e moving from the emitter electrode 11 side toward the collector electrode 10 side, the junction between the p⁻-type collector region 21 and the collector electrode 10 does not serve as an energy barrier irrespective of ohmic contact or Schottky contact. Furthermore, the emitter electrode 11 is applied with a lower potential than the collector electrode 10. Thus, the p-n junction composed of the p⁻-type collector region 21 and the n-type buffer layer 30 is applied with what is called a forward bias. As a result, the electrons e having reached the n-type buffer layer 30 pass through the p-n junction, and then flow through the p⁻-type collector region 21 to the collector electrode 10.

On the other hand, the impurity concentration of the p⁺-type collector region 20 is higher than the impurity concentration of the p⁻-type collector region 21. Thus, the Fermi level of the p⁺-type collector region 20 is lower than the Fermi level of the p⁻-type collector region 21. Accordingly, the energy barrier of the p-n junction composed of the p⁺-type collector region 20 and the n-type buffer layer 30 is raised by the lowered amount of the Fermi level of the p⁺-type collector region 20. That is, the energy barrier of the p-n junction composed of the p⁺-type collector region 20 and the n-type buffer layer 30 is higher than the energy barrier of the p-n junction composed of the p⁻-type collector region 21 and the n-type buffer layer 30.

Thus, for the electrons e having reached the n-type buffer layer 30 from the emitter electrode 11 side, the p-n junction composed of the p⁺-type collector region 20 and the n-type buffer layer 30 is a higher energy barrier than the p-n junction composed of the p⁻-type collector region 21 and the n-type buffer layer 30. As a result, the electrons e having reached the vicinity of the p⁺-type collector region 20 do not easily flow into the p⁺-type collector region 20.

That is, the electrons e having reached the vicinity of the p⁺-type collector region 20 flow laterally (e.g., in the X-direction or Y-direction) so as to avoid the p⁺-type collector region 20. Then, the electrons e flow through the p⁻-type collector region 21 to the collector electrode 10.

By this lateral migration of electrons e and lateral voltage drop of the electron current, the portion 30a of the n-type buffer layer 30 provided above the p⁺-type collector region 20 is negatively biased with respect to the p⁺-type collector region 20 in contact with the collector electrode 10. As described above, the p⁺-type collector region 20 is in ohmic contact with the collector electrode 10. Thus, the portion 30a of the n-type buffer layer 30 is applied with a negative bias also with respect to the collector electrode 10.

This bias effect decreases the energy barrier for holes between the p⁺-type collector region 20 and the portion 30a of the n-type buffer layer 30. When this energy barrier exceeds the threshold, holes are injected from the p⁺-type collector region 20 into the n-type buffer layer 30. The holes injected into the n-type buffer layer 30 form a hole current. In the figure, the hole current based on the holes h is schematically denoted by reference numeral 91.

The hole current 91 increases with the increase of the width in the Y-direction of the p⁺-type collector region 20 or the contact area between the p⁺-type collector region 20 and the collector electrode 10. In other words, the amount of holes injected from the anode side is adjusted by the width W₂₀ or the contact area. Thus, in the on-state of the semiconductor device 1A, holes h flow from the collector side to the emitter side, and electrons e flow from the emitter side to the collector side.

In the mainstream structure of conventional IGBTs, the p-type collector layer is provided on the collector side without being divided into the p⁺-type collector region 20 and the p⁻-type collector region 21. An effective method for accelerating of the speed of the IGBT of such structure is to decrease the impurity concentration of the p-type collector layer to reduce the amount of injected holes h. By this method, the amount of holes injected from the p-type collector layer is generally suppressed. Thus, the speed of the IGBT can be accelerated.

However, decreasing the impurity concentration of the p-type collector layer means decreasing the impurity concentration of the p-type collector layer at the surface in contact with the collector electrode. This results in deteriorating ohmic contact between the p-type collector layer and the collector electrode, and causes a phenomenon in which the switching rate is saturated at a certain rate despite increasing the on-voltage. This is because, while decreasing the impurity concentration of the p-type collector layer accelerates the switching rate, this sharply increases the resistance between the p-type collector layer and the collector electrode. Furthermore, decreasing the impurity concentration of the p-type collector layer also causes a phenomenon of unstable on-voltage depending on each of IGBTs.

In contrast, in the semiconductor device 1A, the hole injection amount is adjusted by combining a high-concentration p⁺-type collector region 20 in ohmic contact with the collector electrode 10 and a low-concentration p⁻-type collector region 21 in ohmic contact or Schottky contact with the collector electrode 10. The hole injection amount can be controlled by the width W₂₀ (or contact area) of the high-concentration p⁺-type collector region 20.

Even if the width W₂₀ of the p⁺-type collector region 20 is adjusted, the impurity concentration of the p⁺-type collector region 20 is not changed. Thus, there is no degradation in ohmic contact between the p⁺-type collector region 20 and the collector electrode 10. This is a great advantage.

Thus, reduction of carriers does not cause the phenomenon of the saturation of switching rate, and the switching rate is accelerated more reliably. Furthermore, because ohmic contact between the p⁺-type collector region 20 and the collector electrode 10 is maintained, the on-voltage of the IGBT is stabilized.

Furthermore, in the semiconductor device 1A, (width W₂₁)/(width W₂₀) is set to e.g. 0.1-10. Thus, the hole injection efficiency can be controlled in a wide range. This can realize a required switching rate depending on the application. Thus, based on one profile design, the semiconductor device 1A can be adapted to various applications from low-rate application to high-rate application simply by changing the dimension of the mask.

Furthermore, the semiconductor device 1A achieves the following effect by the aforementioned impurity concentration profile.

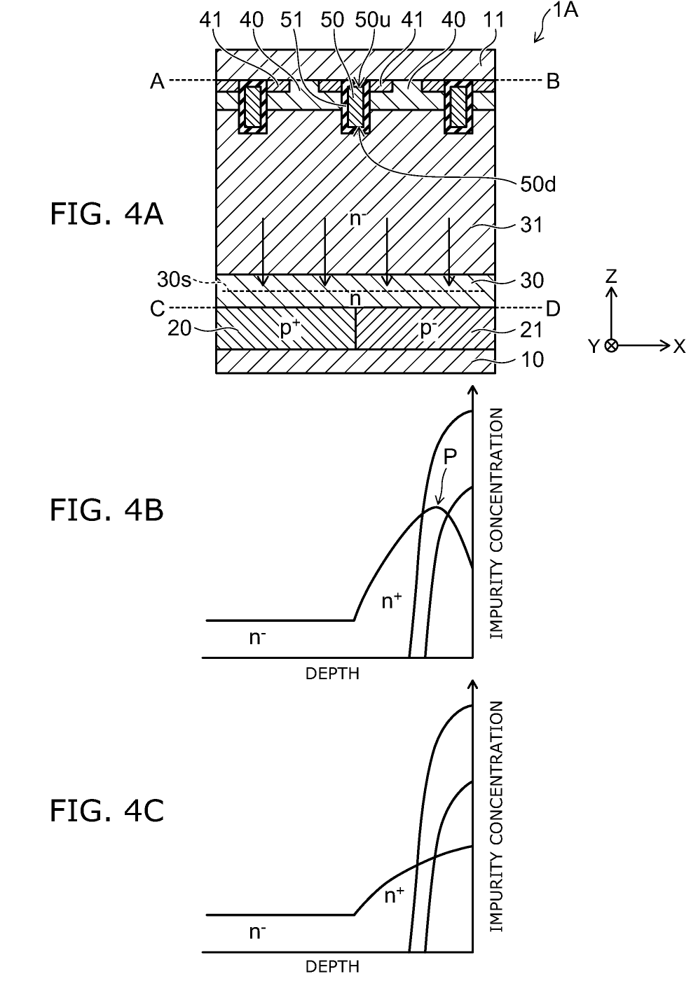

FIG. 4A is a schematic sectional view showing the state after turn-off of the semiconductor device according to the first embodiment. FIGS. 4B and 4C show impurity concentration profiles of semiconductor devices according to reference examples.

In the semiconductor device 1A, the peak P of the impurity concentration profile of the n-type buffer layer 30 is located between the p⁺-type collector region 20 and the p⁻-type collector region 21 on one hand and the n⁻-type base layer 31 on the other. That is, in the semiconductor device 1A, the position, where the total amount of impurity of the n-type buffer layer 30 is maximized, is located in the n-type buffer layer 30.

In the semiconductor device 1A, during off-time, a depletion layer extends from the p-n junction between the p-type base region 40 and the n⁻-type base layer 31 to the n⁻-type base layer 31 side. The depletion layer has the property of extending less easily with the increase of impurity concentration. In FIG. 4A, the extension of the depletion layer is indicated by arrows.

In the semiconductor device 1A, the n-type buffer layer 30 includes the position where its total amount of impurity is maximized. Thus, the extension of the depletion layer is suppressed before the p⁺-type collector region 20 and the p⁻-type collector region 21. For instance, in FIG. 4A, the position of the tip of the depletion layer during off-time is indicated by the line labeled with reference numeral 30s.

If, as shown in FIG. 4B, the peak P is located in the p⁺-type collector region 20 and the p⁻-type collector region 21, or as shown in FIG. 4C, there is no peak, then the depletion layer extending from the p-n junction reaches the p⁺-type collector region 20 and the p⁻-type collector region 21. This causes what is called punch-through.

In contrast, in the semiconductor device 1A, the peak P is located in the n-type buffer layer 30. Thus, the extension of the depletion layer from the p-n junction in the off-state is reliably suppressed in the n-type buffer layer 30. As a result, in the semiconductor device 1A, no punch-through occurs, and a stable operation is ensured.

Furthermore, the position of the peak P of the impurity concentration profile of the n-type buffer layer 30 is located outside the p⁺-type collector region 20 and the p⁻-type collector region 21. Thus, the n-type buffer layer 30, the p⁺-type collector region 20, and the p⁻-type collector region 21 each have an independent impurity concentration profile.

For instance, if the impurity concentration profile of the p⁻-type collector region 21 entirely overlaps the impurity concentration profile of the n-type buffer layer 30, the effective impurity concentration of the p⁻-type collector region 21 decreases. In this case, the p⁻-type collector region 21 effectively fails to be a low-concentration p⁻-type collector region. That is, even if the p⁻-type collector region 21 is formed, the p⁻-type collector region 21 fails to serve its function. In this case, the p⁻-type collector region 21 cannot suppress hole injection. Thus, a phenomenon such as excessive increase of on-voltage occurs.

In the semiconductor device 1A, the n-type buffer layer 30, the p⁺-type collector region 20, and the p⁻-type collector region 21 are each provided with an independent impurity concentration profile to dissolve the aforementioned problem.

Furthermore, the semiconductor device 1A achieves the following effect by setting the thickness of the p⁺-type collector region 20 to 2 μm or less.

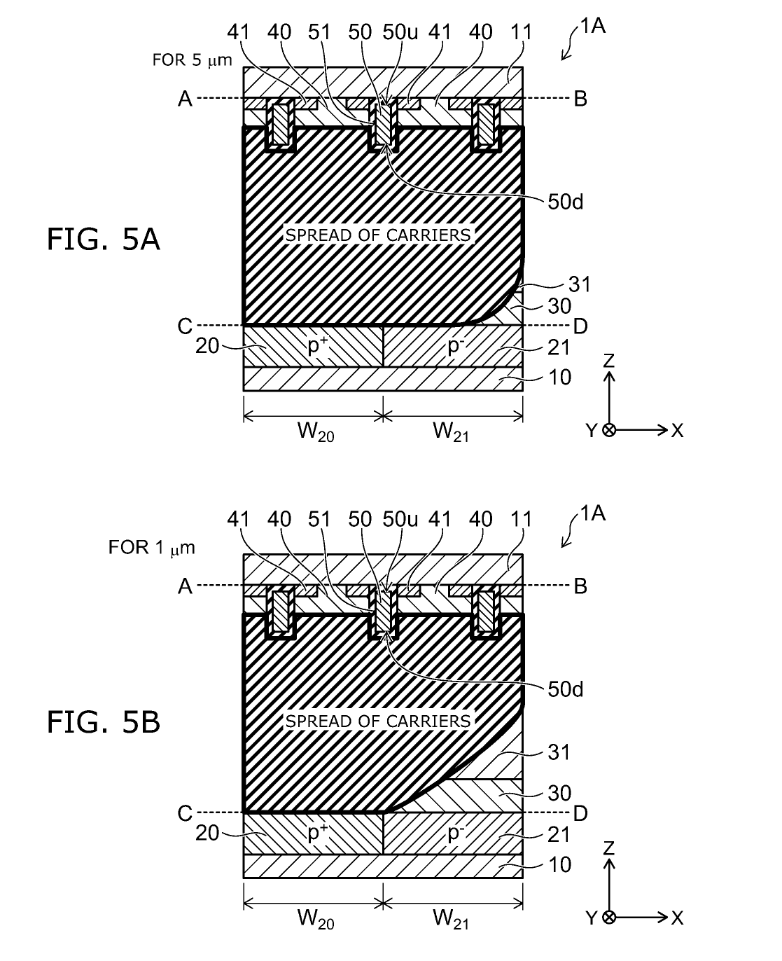

FIGS. 5A and 5B show the result of simulating the state of carriers spreading in the semiconductor device.

FIG. 5A visually shows the state of carriers spreading in the n-type buffer layer 30 and the n⁻-type base layer 31 when the thickness of the p⁺-type collector region 20 is 5 μm. FIG. 5B visually shows the state of carriers spreading in the n-type buffer layer 30 and the n⁻-type base layer 31 when the thickness of the p⁺-type collector region 20 is 1 μm.

As shown in FIG. 5A, when the thickness of the p⁺-type collector region 20 is 5 μm, fast switching of the semiconductor device is difficult even if the p⁺-type collector region 20 and the p⁻-type collector region 21 are made coexistent. This is because, as shown in FIG. 5A, carrier injection of the p⁺-type collector region 20 is excessive, and carriers spread entirely in the n-type buffer layer 30 and entirely in the n⁻-type base layer 31.

On the other hand, as shown in FIG. 5B, when the thickness of the p⁺-type collector region 20 is 1 μm, carriers do not sufficiently spread in part of the n-type buffer layer 30 and part of the n⁻-type base layer 31. Thus, a region having a low carrier density occurs. This means that carrier injection from the p⁺-type collector region 20 is suppressed. Thus, when the thickness of the p⁺-type collector region 20 is approximately 1 μm, fast switching of the semiconductor device is feasible.

The change of the tail current at turn-off time in the case where the thickness of the p⁺-type collector region 20 is 10 μm or less is now described.

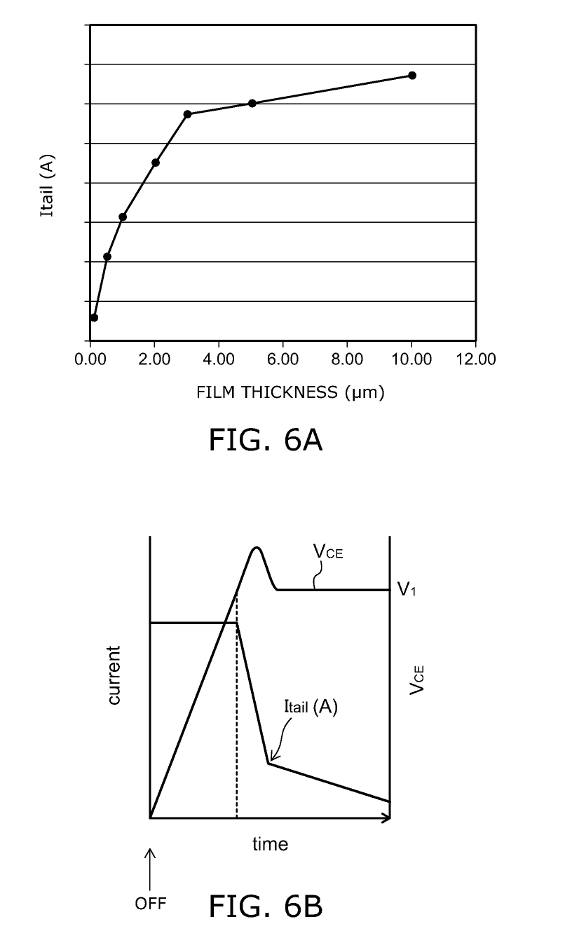

FIG. 6A shows the relationship between the film thickness and the initial value of the tail current (Iₜₐᵢₗ). FIG. 6B shows the current flowing between the emitter and the collector after turn-off.

Along the horizontal axis, FIG. 6B shows the relationship of the emitter-collector current and the emitter-collector voltage (V_{CE}) to the time after the IGBT is turned off.

In the semiconductor device 1A (IGBT), as shown in FIG. 6B, immediately after turn-off, the voltage applied between the emitter and the collector starts to recover. After overshoot of the emitter-collector voltage, the emitter is applied with e.g. a ground potential, and the collector is applied with e.g. a power supply potential (V₁). However, even if the voltage (V₁) is applied between the emitter and the collector, what is called a tail current flows between the emitter and the collector. This is because even after turn-off, carriers remain in e.g. the n⁻-type base layer 31. For fast switching, it is preferable that this tail current be smaller.

As shown in FIG. 6A, it is found that if the thickness of the p⁺-type collector region 20 is 3 μm or less, the initial value of the tail current (Iₜₐᵢₗ) decreases. Furthermore, it is found that if the thickness of the p⁺-type collector region 20 is 2 μm or less, the initial value of the tail current (Iₜₐᵢₗ) sharply decreases. This can significantly reduce the switching loss. That is, it is found that by setting the thickness of the p⁺-type collector region 20 to 2 μm or less, the switching rate of the semiconductor device 1A is made faster.

### Variation of the First Embodiment

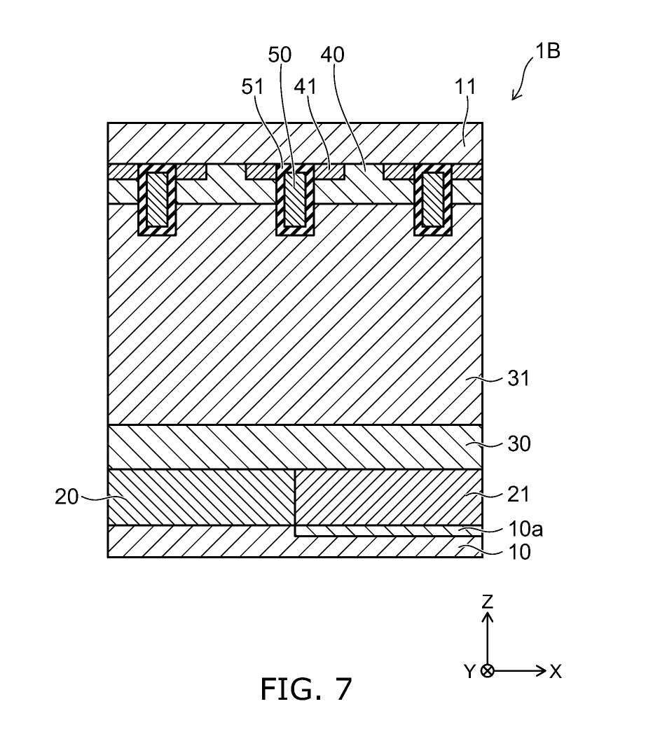

FIG. 7 is a schematic sectional view showing a semiconductor device according to a variation of the first embodiment.

In addition to the structure of the semiconductor device 1A, the structure of the semiconductor device 1B further includes a metal-containing layer 10a different in material from the collector electrode 10 between the collector electrode 10 and the p⁻-type collector region 21. Alternatively, the collector electrode 10 and the metal-containing layer 10a may be collectively referred to as collector electrode.

The material of the metal-containing layer 10a is selected so that the Schottky barrier with the p⁻-type collector region 21 is higher than that for the material of the collector electrode 10. In this case, the Schottky barrier of the junction of the p⁻-type collector region 21 with the metal-containing layer 10a is higher than the Schottky barrier of the direct junction of the p⁻-type collector region 21 with the collector electrode 10. For instance, in the case where the material of the collector electrode 10 is aluminum (Al), titanium (Ti) is selected as the material of the metal-containing layer 10a.

In such structure, hole injection from the collector side is reliably blocked at the junction between the p⁻-type collector region 21 and the metal-containing layer 10a. As a result, the amount of holes injected from the collector side can be reliably controlled by the impurity concentration or width W₂₀ (or contact area) of the p⁺-type collector region 20. Furthermore, the metal material in ohmic contact with the p⁺-type collector region 20 is made different from the metal material in ohmic contact with the p⁻-type collector region 21. This increases the design flexibility of the impurity concentration of each of the p⁺-type collector region 20 and the p⁻-type collector region 21.

It is noted that the metal-containing layer 10a functions also as a barrier layer described later. Furthermore, the metal-containing layer 10a does not need to be provided only between the collector electrode 10 and the p⁻-type collector region 21, but may be provided also between the p⁺-type collector region 20 and the collector electrode 10.

### Alternative Variations of the First Embodiment

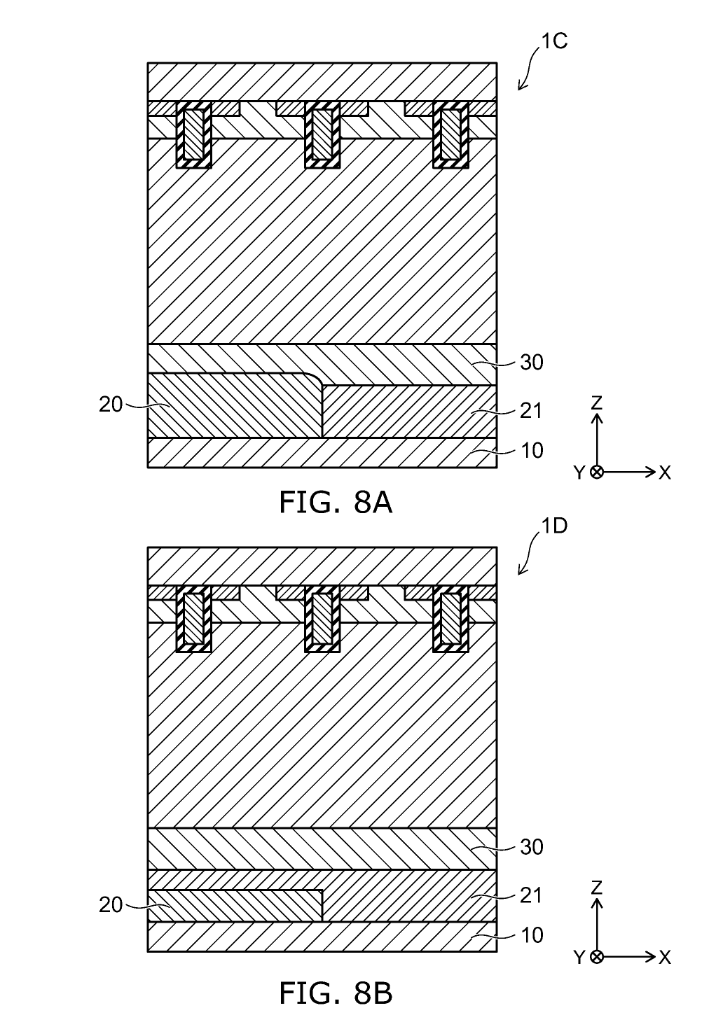

FIGS. 8A and 8B are schematic sectional views showing semiconductor devices according to alternative variations of the first embodiment.

In the examples illustrated in FIGS. 1A and 7, the film thickness of the p⁺-type collector region 20 is equal to the film thickness of the p⁻-type collector region 21. However, the embodiment is not limited to these examples.

For instance, as in the semiconductor device 1C shown in FIG. 8A, the film thickness of the p⁺-type collector region 20 may be thicker than the film thickness of the p⁻-type collector region 21. Alternatively, as in the semiconductor device 1D shown in FIG. 8B, the p⁺-type collector region 20 may be covered with the p⁻-type collector region 21. Such structures also achieve the same function and effect as the semiconductor device 1A.

### Second Embodiment

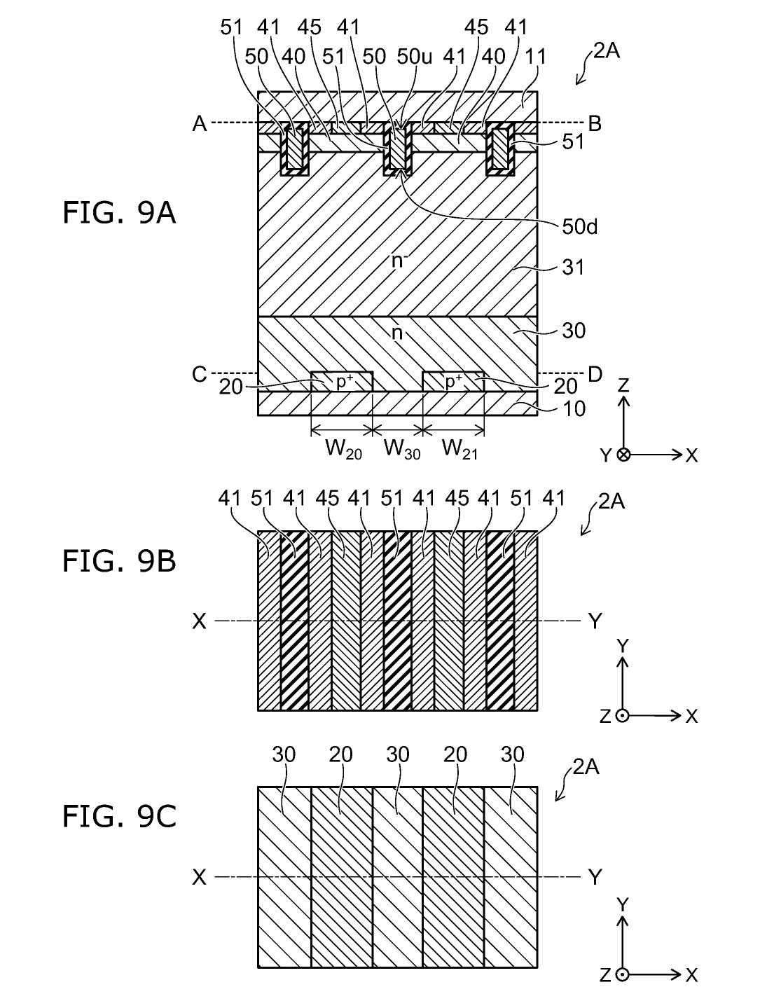

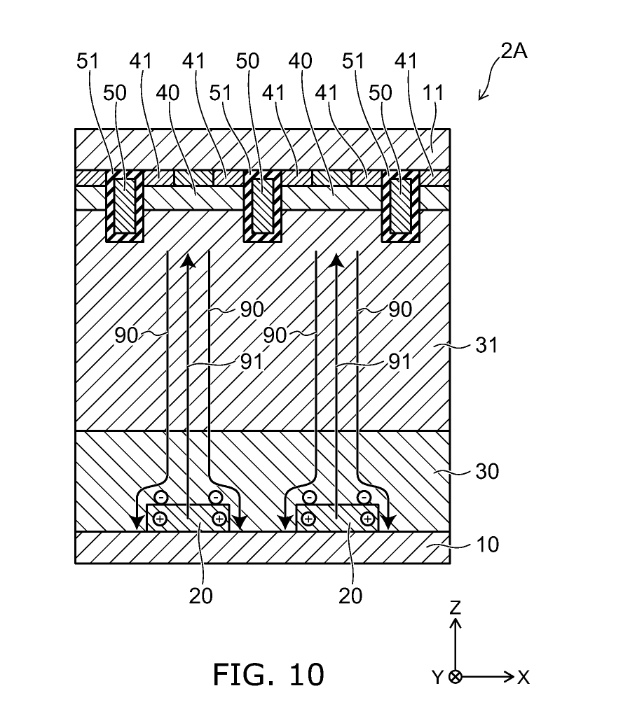

FIGS. 9A to 9C are schematic views showing a semiconductor device according to a second embodiment. FIG. 9A is a schematic sectional view of the semiconductor device. FIGS. 9B and 9C are schematic plan views of the semiconductor device.

FIG. 9A shows a cross section taken along the position of line X-Y in FIGS. 9B and 9C. FIG. 9B shows an A-B cross section of FIG. 9A. FIG. 9C shows a C-D cross section of FIG. 9A.

The semiconductor device 2A shown in FIGS. 9A to 9C is an IGBT. The semiconductor device 2A includes a collector electrode 10 (first electrode), a p⁺-type collector region 20 (first semiconductor region), an n-type buffer layer 30 (first semiconductor layer), an n⁻-type base layer 31 (second semiconductor layer), a p-type base region 40 (third semiconductor region), an n⁺-type emitter region 41 (fourth semiconductor region), a gate electrode 50 (second electrode), a gate insulating film 51, and an emitter electrode 11 (third electrode). Besides, the semiconductor device 2A includes a p⁺-type region 45 functioning as a hole extraction region. The p⁺-type collector region 20, the n-type buffer layer 30, the n⁻-type base layer 31, the p-type base region 40, the n⁺-type emitter region 41, the gate electrode 50, the gate insulating film 51, and the p⁺-type region 45 are provided between the collector electrode 10 and the emitter electrode 11.

In FIGS. 9A to 9C, for instance, a minimum unit of the semiconductor device 2A is shown. In an actual semiconductor device 2A, the semiconductor device 2A shown in FIGS. 9A to 9C is periodically repeated in the X-direction. The length in the Y-direction of FIGS. 9B and 9C is part of the length in the Y-direction of the actual semiconductor device 2A.

The structure of the semiconductor device 2A does not include the p⁻-type collector region 21 included in the structure of the semiconductor device 1A. In the semiconductor device 2A, the aforementioned p⁻-type collector region 21 is replaced by the n-type buffer layer 30. The p⁺-type collector region 20 is provided between part of the collector electrode 10 and the emitter electrode 11. The p⁺-type collector region 20 is in ohmic contact with the collector electrode 10. The n⁻-type base layer 31 is provided between the n-type buffer layer 30 and the emitter electrode 11. The p-type base region 40 is provided between the n⁻-type base layer 31 and the emitter electrode 11. The n⁺-type emitter region 41 is provided between part of the p-type base region 40 and the emitter electrode 11, and is in contact with the emitter electrode 11.

The n-type buffer layer 30 is provided on the collector electrode 10 other than the portion of the collector electrode 10 where the p⁺-type collector region 20 is provided. The n-type buffer layer 30 is provided between the portion other than the part of the collector electrode 10 and the p⁺-type collector region 20 on one hand and the emitter electrode 11 on the other. Furthermore, the n-type buffer layer 30 is provided on the p⁺-type collector region 20. The p⁺-type collector region 20 is covered with the n-type buffer layer 30.

The n-type buffer layer 30 is in Schottky contact with the collector electrode 10. The impurity concentration of the n-type buffer layer 30 is lower than the impurity concentration of the p⁺-type collector region 20. The collector electrode 10 connected to the n-type buffer layer 30 and the collector electrode 10 connected to the p⁺-type collector region 20 are integrated. That is, the n-type buffer layer 30 and the p⁺-type collector region 20 are provided on the same collector electrode 10.

As described above, the semiconductor device 2A shown in FIGS. 9A to 9C is a minimum unit of the IGBT device. In an actual semiconductor device 2A, the p⁺-type collector region 20 in contact with the collector electrode 10 and the n-type buffer layer 30 in contact with the collector electrode 10 are arranged alternately in the X-direction.

The p⁺-type collector region 20 extends in the Y-direction (FIG. 9C). The width W₂₀ in the X-direction of the p⁺-type collector region 20 is e.g. 1-100 μm. The width W₃₀ in the X-direction of the n-type buffer layer 30 sandwiched between the adjacent p⁺-type collector regions 20 is e.g. 1-100 μm. In the arranging direction of the p⁺-type collector region 20 and the n-type buffer layer 30, the width W₂₀ of the p⁺-type collector region 20 and the width W₃₀ of the n-type buffer layer 30 sandwiched between the adjacent p⁺-type collector regions 20 are related as follows. The ratio of (width W₃₀)/(width W₂₀) is equal to e.g. 0.1-10 (0.1 or more and 10 or less).

The thickness of the p⁺-type collector region 20 is several tens μm or less. More preferably, the thickness of the p⁺-type collector region 20 is 2 μm or less (described above).

The concentration of the impurity element contained in the n⁻-type base layer 31 is lower than the concentration of the impurity element contained in the n⁺-type emitter region 41. The concentration of the impurity element contained in the n⁻-type base layer 31 is lower than the concentration of the impurity element contained in the n-type buffer layer 30.

The concentration of the impurity element contained in the p⁺-type collector region 20 is higher than the concentration of the impurity element contained in the n-type buffer layer 30. For instance, the concentration of the impurity element contained in the p⁺-type collector region 20 at the surface in contact with the collector electrode 10 is higher than the concentration of the impurity element contained in the n-type buffer layer 30 at the surface in contact with the collector electrode 10.

The concentration of the impurity element contained in the p⁺-type collector region 20 at the surface in contact with the collector electrode 10 is higher than 3×10¹⁷ atoms.cm⁻³, such as 1×10¹⁹ atoms.cm⁻³ or more. The impurity concentration of the p⁺-type collector region 20 may be set higher toward the collector electrode 10 side.

The impurity concentration at the peak position of the impurity concentration profile of the n-type buffer layer 30 is e.g. 1×10¹⁵-1×10¹⁷ atoms.cm⁻³. For instance, the impurity concentration of the n-type buffer layer 30 at the surface in contact with the collector electrode 10 is e.g. 3×10¹⁷ cm⁻³ or less. The impurity concentration of the n-type buffer layer 30 may be set lower toward the collector electrode 10 side.

The operation of the semiconductor device 2A is now described.

In operating the semiconductor device 2A, the emitter electrode 11 is applied with a ground potential (or negative potential), and the collector electrode 10 is applied with a positive potential. Between the emitter electrode 11 and the collector electrode 10, a voltage of e.g. several hundred V is applied.

In the off-state of the semiconductor device 2A, the potential of the gate electrode 50 is lower than the threshold potential. Thus, no channel region (inversion layer) is formed in the p-type base region 40 along the gate electrode 50 via the gate insulating film 51. Accordingly, no current flows between the emitter electrode 11 and the collector electrode 10.

The on-state of the semiconductor device 2A is now described.

FIG. 10 is a schematic sectional view showing the operation of the on-state of the semiconductor device according to the second embodiment.

If the potential of the gate electrode 50 of the semiconductor device 2A increases to the threshold potential or more, the semiconductor device 2A is turned on. Then, a channel region is formed in the p-type base region 40. Thus, electrons e injected from the emitter electrode 11 into the n⁺-type emitter region 41 pass through the channel region of the p-type base region 40 to the n⁻-type base layer 31. Furthermore, the electrons e reach the n-type buffer layer 30. In the figure, the electron current based on the electrons e is schematically denoted by reference numeral 90.

In the semiconductor device 2A, the n-type buffer layer 30 and the collector electrode 10 are in Schottky contact with each other. Thus, for electrons e moving from the emitter electrode 11 side toward the collector electrode 10 side, the junction between the n-type buffer layer 30 and the collector electrode 10 serves as an energy barrier.

On the other hand, the impurity concentration of the p⁺-type collector region 20 is set high. Thus, the energy barrier of the p-n junction composed of the p⁺-type collector region 20 and the n-type buffer layer 30 is raised by the lowered amount of the Fermi level of the p⁺-type collector region 20. Here, for electrons e moving from the emitter electrode 11 side toward the collector electrode 10 side, the energy barrier of the p-n junction composed of the p⁺-type collector region 20 and the n-type buffer layer 30 is set higher than the energy barrier of the Schottky contact composed of the n-type buffer layer 30 and the collector electrode 10.

Thus, for the electrons e having reached the n-type buffer layer 30 from the emitter electrode 11 side, the p-n junction composed of the p⁺-type collector region 20 and the n-type buffer layer 30 is an energy barrier. As a result, the electrons e having reached the vicinity of the p⁺-type collector region 20 do not easily flow into the p⁺-type collector region 20.

That is, the electrons e having reached the vicinity of the p⁺-type collector region 20 flow laterally (e.g., in the X-direction or Y-direction) so as to avoid the p⁺-type collector region 20. Then, the electrons e flow through the n-type buffer layer 30 located beside the p⁺-type collector region 20 to the collector electrode 10.

By this lateral migration of electrons e and lateral voltage drop of the electron current, the portion 30a of the n-type buffer layer 30 provided above the p⁺-type collector region 20 is negatively biased with respect to the p⁺-type collector region 20 in contact with the collector electrode 10. As described above, the p⁺-type collector region 20 is in ohmic contact with the collector electrode 10. Thus, the portion 30a of the n-type buffer layer 30 is applied with a negative bias also with respect to the collector electrode 10.

This bias effect decreases the energy barrier for holes between the p⁺-type collector region 20 and the portion 30a of the n-type buffer layer 30. When this energy barrier exceeds the threshold, holes are injected from the p⁺-type collector region 20 into the n-type buffer layer 30. The holes injected into the n-type buffer layer 30 form a hole current. In the figure, the hole current based on the holes h is schematically denoted by reference numeral 91.

The hole current 91 increases with the increase of the width W₂₀ in the Y-direction of the p⁺-type collector region 20 or the contact area between the p⁺-type collector region 20 and the collector electrode 10. In other words, the amount of holes injected from the anode side is adjusted by the width or the contact area. Thus, in the on-state of the semiconductor device 2A, holes h flow from the collector side to the emitter side, and electrons e flow from the emitter side to the collector side.

In the semiconductor device 2A, the hole injection amount is adjusted by combining a high-concentration p⁺-type collector region 20 in ohmic contact with the collector electrode 10 and a low-concentration n-type buffer layer 30 in Schottky contact with the collector electrode 10. The hole injection amount can be controlled by the width W₂₀ (or contact area) of the high-concentration p⁺-type collector region 20.

Even if the width W₂₀ of the p⁺-type collector region 20 is adjusted, the impurity concentration of the p⁺-type collector region 20 is not changed. Thus, there is little degradation in ohmic contact between the p⁺-type collector region 20 and the collector electrode 10.

Thus, increasing the on-voltage is less likely to cause the phenomenon of the saturation of switching rate, and the switching rate is accelerated more reliably. Furthermore, because ohmic contact between the p⁺-type collector region 20 and the collector electrode 10 is maintained, the on-voltage of the IGBT is stabilized.

In the foregoing description, for electrons e moving from the emitter electrode 11 side toward the collector electrode 10 side, the junction between the n-type buffer layer 30 and the collector electrode 10 serves as a Schottky barrier.

If the n-type buffer layer 30 and the collector electrode 10 are in ohmic contact with each other, then when the IGBT is reverse biased, the p-n diode formed from the p-type base region 40, the n⁻-type base layer 31, and the n-type buffer layer 30 is operated and may cause breakdown. For instance, in the reverse biased state of the IGBT, the potential is higher on the emitter side than on the collector side. In this case, the aforementioned p-n diode is forward biased and turned on.

To avoid such trouble, in the semiconductor device 2A, the contact between the n-type buffer layer 30 and the collector electrode 10 is formed as a Schottky contact. That is, even if the aforementioned diode is applied with a forward bias, injection of electrons from the collector side into the n-layer (n-type buffer layer 30 and n⁻-type base layer 31) of the p-n diode is suppressed by the Schottky barrier to suppress the operation of the aforementioned diode. Thus, the semiconductor device 2A has a high breakdown withstand capability.

Furthermore, in the semiconductor device 2A, (width W₃₀)/(width W₂₀) is set to e.g. 0.1-10. Thus, the hole injection efficiency can be controlled in a wide range. This can realize a required switching rate depending on the application. Thus, based on one profile design, the semiconductor device 2A can be adapted to various applications from low-rate application to high-rate application simply by changing the dimension of the mask.

### Variation of the Second Embodiment

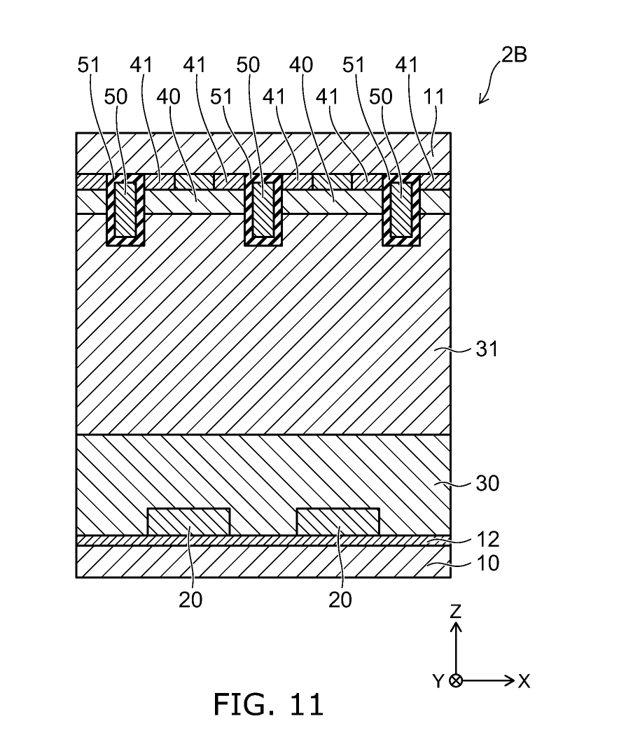

FIG. 11 is a schematic sectional view showing a semiconductor device according to a variation of the second embodiment.

In addition to the structure of the semiconductor device 2A, the structure of the semiconductor device 2B further includes a metal-containing layer 12 different in material from the collector electrode 10 between the collector electrode 10 on one hand and the p⁺-type collector region 20 and the n-type buffer layer 30 on the other.

When the collector side of the IGBT is mounted on a circuit substrate such as an interposer and printed circuit board, a spike may occur on the collector electrode 10 side due to thermal history of solder bonding and the like. The spike may also occur in annealing for proton donor formation on the collector side of the IGBT.

For instance, in the case of the aforementioned mounting, when the collector electrode 10 includes aluminum, the spike refers to penetration of aluminum to the p⁺-type collector region 20, the n-type buffer layer 30 and the like on the collector electrode 10.

In the semiconductor device 2B, for instance, when the collector electrode 10 includes aluminum, the metal-containing layer 12 containing titanium is provided between the collector electrode 10 on one hand and the p⁺-type collector region 20 and the n-type buffer layer 30 on the other. As a result, the metal-containing layer 12 serves as a barrier film to suppress the occurrence of the aforementioned spike.

Furthermore, the impurity concentration of the p⁺-type collector region 20 of the semiconductor device 2B is set higher than the impurity concentration of the p⁺-type collector region of the semiconductor device 2A. This achieves good ohmic contact between the p⁺-type collector region 20 and the metal-containing layer 12.

### Third Embodiment

The embodiments are not limited to the foregoing embodiments.

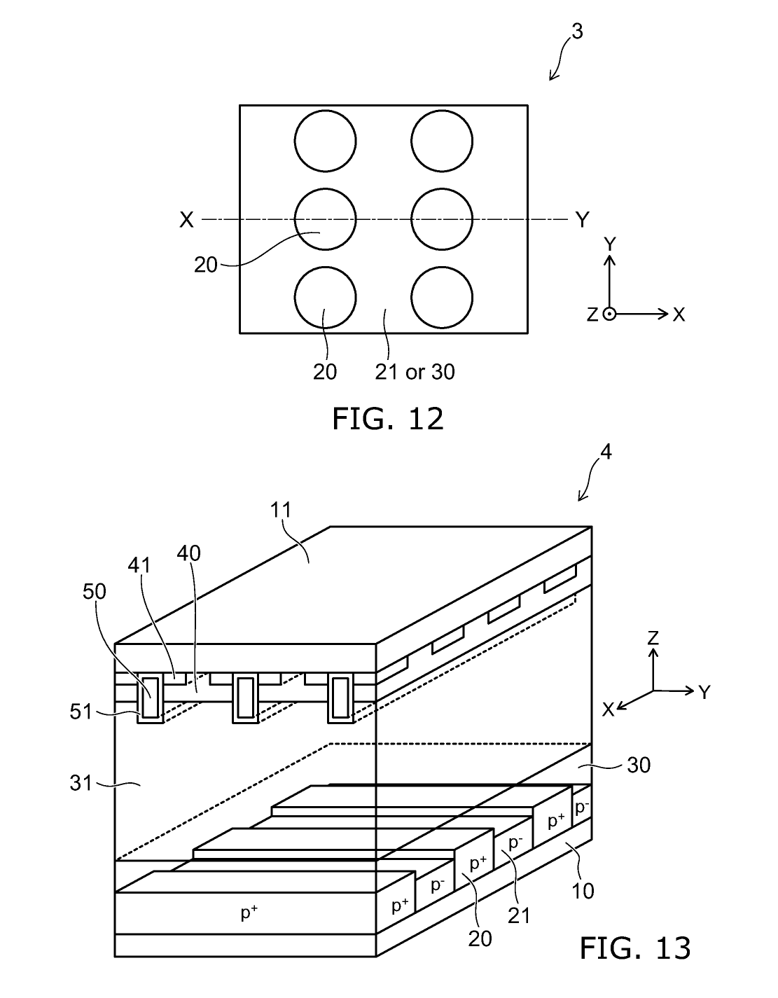

FIG. 12 is a schematic plan view showing a semiconductor device according to a third embodiment.

FIG. 12 corresponds to the aforementioned C-D cross section.

The planar shape of the p⁺-type collector region 20 may be a circular shape, besides the striped shape extending in the Y-direction.

For instance, in the semiconductor device 3 shown in FIG. 12, the planar shape of the p⁺-type collector region 20 in the C-D cross section is circular. In the semiconductor device 3, in the C-D cross section, each of a plurality of p⁺-type collector regions 20 is surrounded with the p⁻-type collector region 21 or the n-type buffer layer 30.

Also in such structure, the amount of holes injected from the anode side is adjusted by the width of the p⁺-type collector region 20 or its contact area with the collector electrode 10.

### Fourth Embodiment

FIG. 13 is a schematic plan view showing a semiconductor device according to a fourth embodiment.

In the semiconductor device 4, the p⁺-type collector region 20 and the p⁻-type collector region 21 extend in the Y-direction. The gate electrode 50 extends in the X-direction. In the figure, the gate electrode 50 and the n⁺-type emitter region 41 are shown as being discontinuous in places in the X-direction. However, the gate electrode 50 and the n⁺-type emitter region 41 may extend continuously in the X-direction. Here, the structure shown in FIG. 13 with the p⁻-type collector region 21 omitted therefrom is also encompassed within the scope of this embodiment.

On the emitter side, a trench gate extends in the X-direction. Thus, the electron current flowing from the emitter electrode 11 side toward the collector electrode 10 side is likely to be nonuniform. For instance, the electron current is larger below the channel formed in the p-type base region 40, and becomes smaller with the distance from this channel.

Furthermore, if the p⁺-type collector region 20 and the p⁻-type collector region 21 on the collector electrode 10 side are arranged in the same X-direction, the hole current also becomes nonuniform. This may cause breakdown of the semiconductor device at turn-off from large current.

Thus, if the electron current flowing from the emitter electrode 11 side toward the collector electrode 10 side and the hole current flowing from the p⁺-type collector region toward the emitter electrode 11 side are both nonuniform, a great nonuniformity occurs entirely. This may cause breakdown of the semiconductor device at turn-off from large current.

In the fourth embodiment, the extending direction of the p⁺-type collector region 20 and the p⁻-type collector region 21 is crossed with the extending direction of the gate electrode 50. Such structure relaxes the nonuniformity of the electron current and the hole current. Thus, the current flowing in the IGBT is made uniform. As a result, the breakdown withstand capability at turn-off time is increased.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

In the examples illustrated in the embodiments, the main component of the semiconductor is silicon (Si). However, the main component of the semiconductor may be silicon carbide (SiC), gallium nitride (GaN) or the like. Furthermore, with regard to the conductivity type, in the embodiments, the first conductivity type is p-type, and the second conductivity type is n-type. However, it is obvious that a similar effect is achieved also in the device in which the first conductivity type is n-type and the second conductivity type is p-type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode;
a first semiconductor region of a first conductivity type provided between part of the first electrode and the second electrode, and the first semiconductor region being in ohmic contact with the first electrode;
a second semiconductor region of the first conductivity type provided between a portion other than the part of the first electrode and the second electrode, the second semiconductor region being in contact with the first semiconductor region and the first electrode, and the second semiconductor region having a lower impurity concentration than the first semiconductor region;
a first semiconductor layer of a second conductivity type provided between the first semiconductor region and the second electrode and provided between the second semiconductor region and the second electrode;
a second semiconductor layer of the second conductivity type provided between the first semiconductor layer and the second electrode;
a third semiconductor region of the first conductivity type provided between the second semiconductor layer and the second electrode;
a fourth semiconductor region of the second conductivity type provided between part of the third semiconductor region and the second electrode, and the fourth semiconductor region being in contact with the second electrode; and
a third electrode in contact with the second semiconductor layer, the third semiconductor region and the fourth semiconductor region via an insulating film,
a peak of impurity concentration profile of the first semiconductor layer in a direction from the first electrode toward the second electrode being located between the first semiconductor region and the second semiconductor layer and located between the second semiconductor region and the second semiconductor layer.

2. The device according to claim 1, wherein the second semiconductor region is in ohmic contact or Schottky contact with the first electrode.

3. The device according to claim 1, wherein thickness of the first semiconductor region is 2 micrometers or less.

4. The device according to claim 1, wherein
the first semiconductor region and the second semiconductor region extend in a second direction crossing a first direction from the first electrode toward the second electrode, and
the third electrode extends in a third direction crossing the first direction and the second direction.

5. The device according to claim 1, further comprising:
a metal-containing layer different in material from the first electrode between the first electrode and the second semiconductor region.

6. The device according to claim 5, wherein the metal-containing layer is provided further between the first electrode and the first semiconductor region.

7. The device according to claim 1, wherein width Wₒ of the first semiconductor region and width W₁ of the second semiconductor region in an arranging direction of the first semiconductor region and the second semiconductor region are related as
0.1≦width W₁/width W₀≦10.

8. The device according to claim 1, wherein thickness of the first semiconductor region and thickness of the second semiconductor region are different.

9. A semiconductor device comprising:
a first electrode;
a second electrode;
a first semiconductor region of a first conductivity type provided between part of the first electrode and the second electrode, the first semiconductor region being in ohmic contact with the first electrode, and the first semiconductor region having a thickness of 2 micrometers or less;
a second semiconductor region of the first conductivity type provided between a portion other than the part of the first electrode and the second electrode, the second semiconductor region being in contact with the first semiconductor region and the first electrode, and the second semiconductor region having a lower impurity concentration than the first semiconductor region;
a first semiconductor layer of a second conductivity type provided between the first semiconductor region and the second electrode and provided between the second semiconductor region and the second electrode;
a second semiconductor layer of the second conductivity type provided between the first semiconductor layer and the second electrode;
a third semiconductor region of the first conductivity type provided between the second semiconductor layer and the second electrode;
a fourth semiconductor region of the second conductivity type provided between part of the third semiconductor region and the second electrode, and the fourth semiconductor region being in contact with the second electrode; and
a third electrode in contact with the second semiconductor layer, the third semiconductor region and the fourth semiconductor region via an insulating film.

10. The device according to claim 9, wherein a peak of impurity concentration profile of the first semiconductor layer in a direction from the first electrode toward the second electrode is located between the first semiconductor region and the second semiconductor layer and located between the second semiconductor region and the second semiconductor layer.

11. The device according to claim 9, wherein the second semiconductor region is in ohmic contact or Schottky contact with the first electrode.

12. The device according to claim 9, wherein
the first semiconductor region and the second semiconductor region extend in a second direction crossing a first direction from the first electrode toward the second electrode, and
the third electrode extends in a third direction crossing the first direction and the second direction.

13. The device according to claim 9, further comprising:
a metal-containing layer different in material from the first electrode between the first electrode and the second semiconductor region.

14. The device according to claim 13, wherein the metal-containing layer is provided further between the first electrode and the first semiconductor region.

15. The device according to claim 9, wherein width W₀ of the first semiconductor region and width W₁ of the second semiconductor region in an arranging direction of the first semiconductor region and the second semiconductor region are related as
0.1≦width W₁/width W₀≦10.

16. A semiconductor device comprising:
a first electrode;
a second electrode;
a first semiconductor region of a first conductivity type provided between part of the first electrode and the second electrode, and the first semiconductor region being in ohmic contact with the first electrode;
a first semiconductor layer of a second conductivity type provided between a portion other than the part of the first electrode and the second electrode and provided between the first semiconductor region and the second electrode, the first semiconductor layer being in Schottky contact with the first electrode, and the first semiconductor layer having a lower impurity concentration than the first semiconductor region;
a second semiconductor layer of the second conductivity type provided between the first semiconductor layer and the second electrode;
a third semiconductor region of the first conductivity type provided between the second semiconductor layer and the second electrode;
a fourth semiconductor region of the second conductivity type provided between part of the third semiconductor region and the second electrode, and the fourth semiconductor region being in contact with the second electrode; and
a third electrode in contact with the second semiconductor layer, the third semiconductor region, and the fourth semiconductor region via an insulating film.

17. The device according to claim 16, wherein
the first semiconductor region extends in a second direction crossing a first direction from the first electrode toward the second electrode, and
the third electrode extends in a third direction crossing the first direction and the second direction.

18. The device according to claim 16, further comprising:
a metal-containing layer different in material from the first electrode between the first electrode and the first semiconductor region and between the first electrode and the first semiconductor layer.

19. The device according to claim 16, wherein thickness of the first semiconductor region is 2 micrometers or less.

20. The device according to claim 16, wherein width Wₒ of the first semiconductor region and width W₃ of the first semiconductor layer sandwiched between adjacent ones of the first semiconductor regions in an arranging direction of the first semiconductor region and the first semiconductor layer are related as
0.1≦width W₃/width W₀≦10.
